(19) United States
(12) Patent Application Publication
(10) Pub. No.: US 2022/0246813 A1
(43) Pub. Date: Aug. 4, 2022

(54) LIGHT-EMITTING DEVICE AND METHOD FOR MANUFACTURING THE SAME

(71) Applicant: Lextar Electronics Corporation, Hsinchu (TW)

(72) Inventors: Lung-Kuan LAI, Hsinchu (TW); Jian-Chin LIANG, Hsinchu (TW)

(21) Appl. No.: 17/572,649

(22) Filed: Jan. 11, 2022

(30) Foreign Application Priority Data
Jan. 29, 2021 (TW) 110103577

(51) Int. Cl. H01L 33/62; H01L 25/075

(52) U.S. Cl. CPC H01L 33/62; H01L 33/60; H01L 25/0753

(57) ABSTRACT

A light-emitting device includes a substrate, a circuit layer, a plurality of conductive connection portions, and a plurality of semiconductor light-emitting sources. The circuit layer on the substrate having a plurality of conductive structures, in which each conductive structure includes at least one bonding pad. An interval is between two adjacent ones of the conductive structures. Each conductive connection portion is correspondingly located on each bonding pad. Each semiconductor light-emitting source crosses each interval and contacts two adjacent ones of the conductive connection portions, such that the semiconductor light-emitting sources are respectively electrically connected to two adjacent ones of the conductive structures.

### CROSS-REFERENCE TO RELATED APPLICATION

This application claims priority to Taiwan Application Serial Number 110103577, filed Jan. 29, 2021, which is herein incorporated by reference in its entirety.

### BACKGROUND

### Field of Invention

The present invention relates to a light-emitting device and a method for manufacturing the same.

### Description of Related Art

Light-emitting diode devices have been widely used in a variety of products, and the printed circuit boards used to carry and conduct the light-emitting diodes also need to be miniaturized for matching the development trend of products that are lighter, thinner, and smaller.

In many cases, the traditional printed circuit boards no longer meet the requirements of increasingly sophisticated techniques.

### SUMMARY

The invention provides a light-emitting device which includes a substrate, a circuit layer, a plurality of conductive connection portions, and a plurality of semiconductor light-emitting sources. The circuit layer located on the substrate having a plurality of conductive structures, in which each conductive structure includes at least one bonding pad. An interval is located between two adjacent ones of the conductive structures. Each conductive connection portion is correspondingly located on each bonding pad. Each semiconductor light-emitting source crosses each interval and contacts two adjacent ones of the conductive connection portions, such that the semiconductor light-emitting sources are respectively electrically connected to the two adjacent ones of conductive structures.

In some embodiments of the present disclosure, the light-emitting device includes a reflective layer disposed on the circuit layer and covering the conductive structures. The reflective layer has a plurality of openings, and the opening are respectively aligned with each interval, the at least one bonding pad is disposed in each opening.

In some embodiments of the present disclosure, the conductive connection portions respectively contact sidewalls of the reflective layer.

In some embodiments of the present disclosure, the conductive connection portions are separated from sidewalls of the reflective layer.

In some embodiments of the present disclosure, the conductive connection portions include copper, nickel, palladium, silver, gold, tin, or alloy thereof.

In some embodiments of the present disclosure, the conductive connection portions are made from copper slurry, silver slurry, gold slurry, or solder paste.

In some embodiments of the present disclosure, each semiconductor light-emitting source includes a light-emitting diode chip which has two electrodes respectively on the two adjacent conductive connection portions.

In some embodiments of the present disclosure, each electrode is not higher than a top surface of the reflective layer.

In some embodiments of the present disclosure, the reflective layer includes a white reflective layer or a metal reflective layer.

Another aspect of the present invention provides a method for manufacturing a light-emitting device which includes providing a substrate; forming a circuit layer which has a plurality of conductive structures on the substrate, in which in each conductive structure has a least one bonding pad, and an intervals is formed between two adjacent ones of the conductive structures; forming a plurality of conductive connection portions, and each conductive connection portion is correspondingly located on each bonding pad; and providing a plurality of semiconductor light-emitting sources, in which each semiconductor light-emitting source crosses each interval and contacts two adjacent ones of the conductive connection portions, such that the semiconductor light-emitting sources are respectively electrically connected to the two adjacent ones of conductive structures.

In some embodiments of the present disclosure, forming the plurality of conductive connection portions further includes providing a reflective layer covering the conductive structures, and the reflective layer has a plurality of openings respectively aligned with each interval, each interval exposes the bonding pad of each two adjacent conductive structures; forming a seed layer which covers a top surface of the reflective layer and extends along sidewalls of the openings to cover the exposed bonding pads; forming a photoresist layer on the seed layer, in which the photoresist layer exposes the partial seed layer on the bonding pads; and using the seed layer to form the conductive connection portions.

In some embodiments of the present disclosure, a portion of the seed layer on a top surface of the reflective layer is covered by the photoresist layer.

In some embodiments of the present disclosure, a portion of the seed layer which extends from a top surface of the reflective layer to sidewalls of the openings is covered by the photoresist layer.

In some embodiments of the present disclosure, forming the conductive connection portions includes forming a plurality of thickening portions from the seed layer; removing the photoresist layer; and partially removing the seed layer.

In some embodiments of the present disclosure, forming the conductive connection portions includes forming a plurality of thickening portions on the seed layer; removing the photoresist layer; and removing a portion of the seed layer which is on a top surface of the reflective layer.

In some embodiments of the present disclosure, the seed layer includes copper, nickel, palladium, silver, gold, tin, or alloy thereof.

In some embodiments of the present disclosure, forming the conductive connection portions includes: performing a printing process or a spraying process to form conductive slurry on each bonding pad.

In some embodiments of the present disclosure, the printing process is a paste printing process.

In some embodiments of the present disclosure, forming the conductive connection portions includes providing a reflective layer covering the conductive structures, and the reflective layer has a plurality of openings respectively aligned with each interval, the at least one bonding pad is disposed in each opening; and performing a printing process or a spraying process in each opening to form conductive slurry on each bonding pad, so as to form the conductive connection portions, and the conductive connection portions respectively contact sidewalls of the reflective layer.

In some embodiments of the present disclosure, each semiconductor light-emitting source includes a light emitting diode chip which has two electrodes respectively electrically connected to the two adjacent conductive connection portions in a flip-chip manner.

In embodiments of the present disclosure, a light-emitting device which has conductive connection portions and a method for fabricating the same are provided, and the conductive connection portions can be stably connected between semiconductor light-emitting source and bonding pads, so as to improve the conductive property and the mechanical property thereof. Moreover, the light-emitting deice can be applied in various light-emitting apparatuses, display apparatuses, and back light modules of liquid crystal display apparatuses.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1A illustrates a schematic view of a light-emitting device in accordance with some embodiments of the present disclosure.

FIG. 1B illustrates a schematic view of a light-emitting device in accordance with some embodiments of the present disclosure.

FIGS. 2A and 2B illustrate a flow chart of a method for manufacturing the light-emitting device in FIG. 1A.

FIGS. 3A-3H illustrate cross section views representing steps of the method in FIG. 2A and 2B, wherein FIG. 3H can represent the cross section view taken from the cross section line A-A in FIG. 1A.

FIGS. 4A-4H illustrate cross section views representing steps of the method in FIG. 2A and 2B, wherein FIG. 4H can represent the cross section view taken from the cross section line A-A in FIG. 1A.

FIGS. 5A-5E illustrate cross section views representing steps of the method in FIG. 2A and 2B, wherein FIG. 5E can represent the cross section view taken from the cross section line A-A in FIG. 1A.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

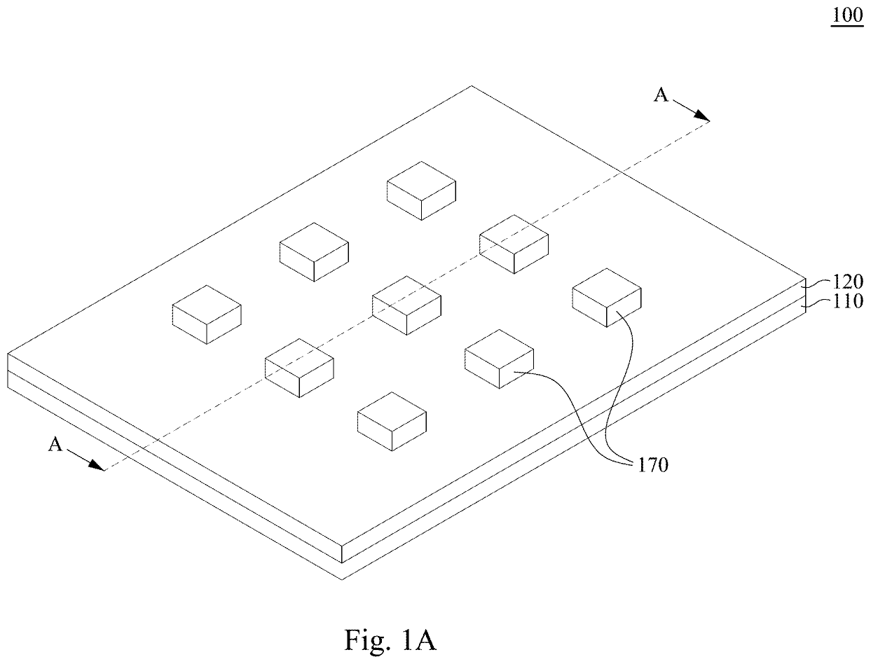

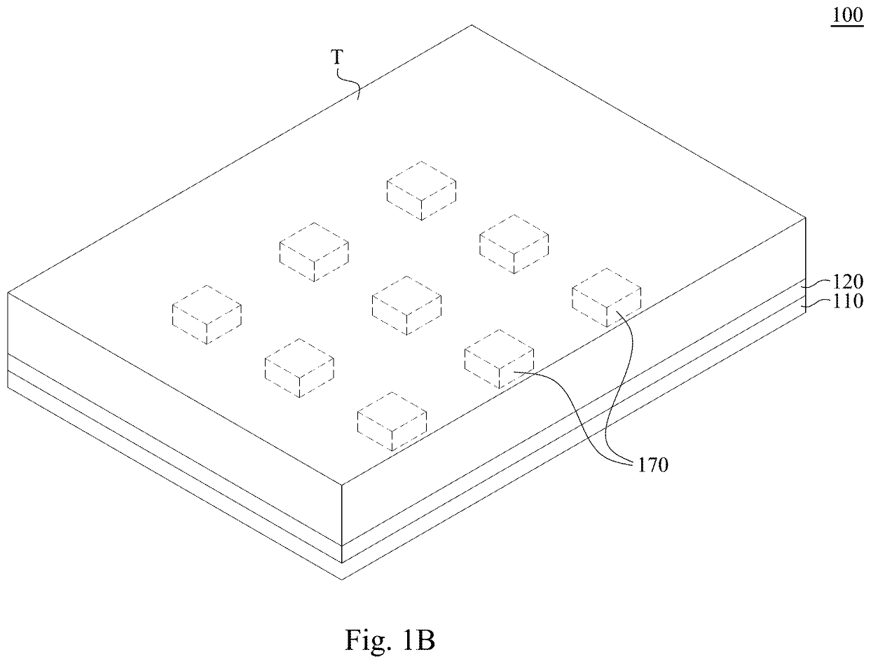

Reference is made to FIG. 1A. FIG. 1A illustrates a schematic view of a light-emitting device 100. The light-emitting device 100 includes a substrate 110, a circuit layer 120, and a plurality of semiconductor light-emitting sources 170. The circuit layer 120 is located on the substrate 110, and the semiconductor light-emitting sources 170 are on the circuit layer 120. The semiconductor light-emitting sources 170 are electrically connected to circuit structures of the circuit layer 120, and the semiconductor light-emitting sources 170 can be light-emitting diode light sources, such as, but not limited to light-emitting diode (LED) chips, mini LED chips or micro LED chips which have smaller size. In some embodiments, the light-emitting device 100 further includes a transparent layer T which covers the circuit layer 120 and the semiconductor light-emitting sources 170 as shown in FIG. 1B. The refractive index of the transparent layer T is from about 1.49 to about 1.6. The transparent layer T can include silicone resin, epoxy resin, or Acrylic (Poly(methyl methacrylate)). The present disclosure is not limited in this respect. The methods for manufacturing the light-emitting device 100 and the details thereof are described as below.

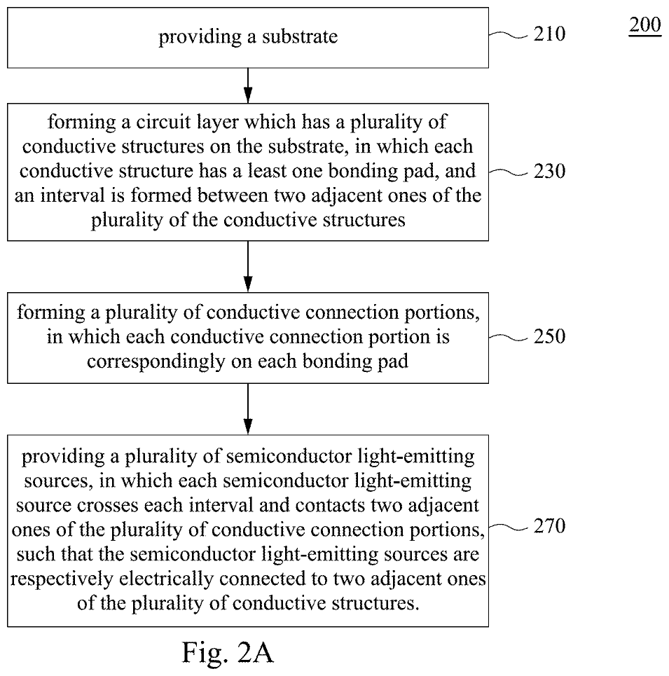

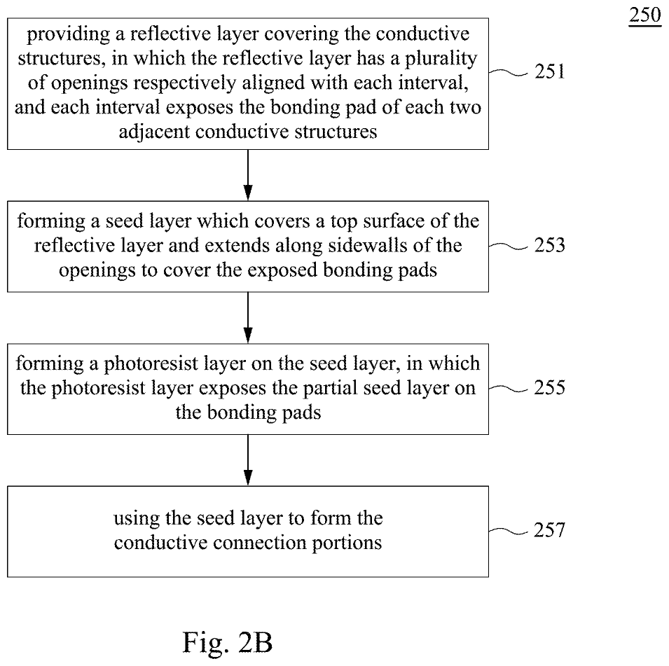

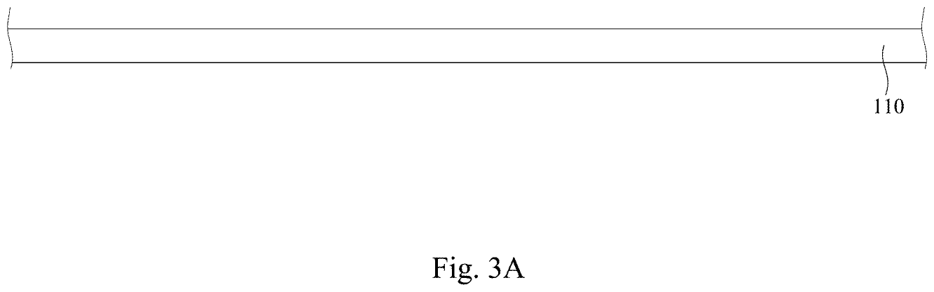

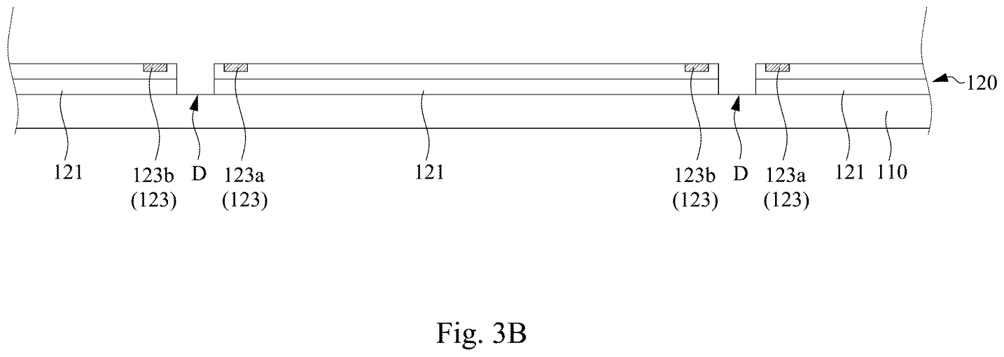

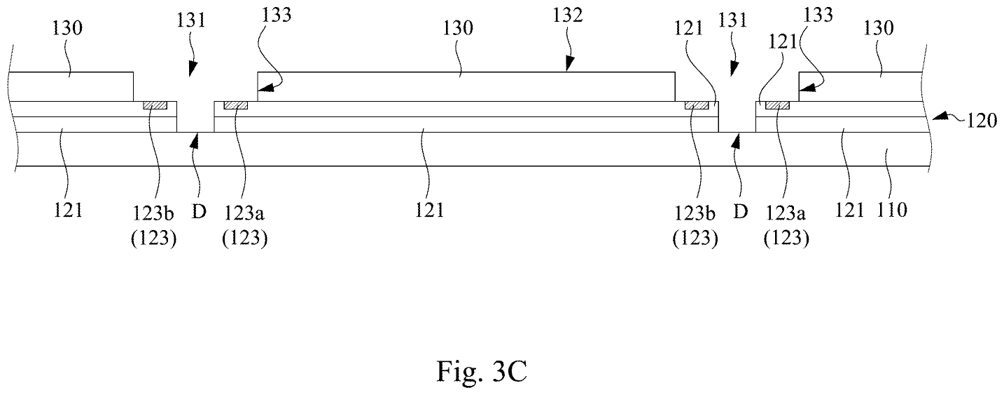

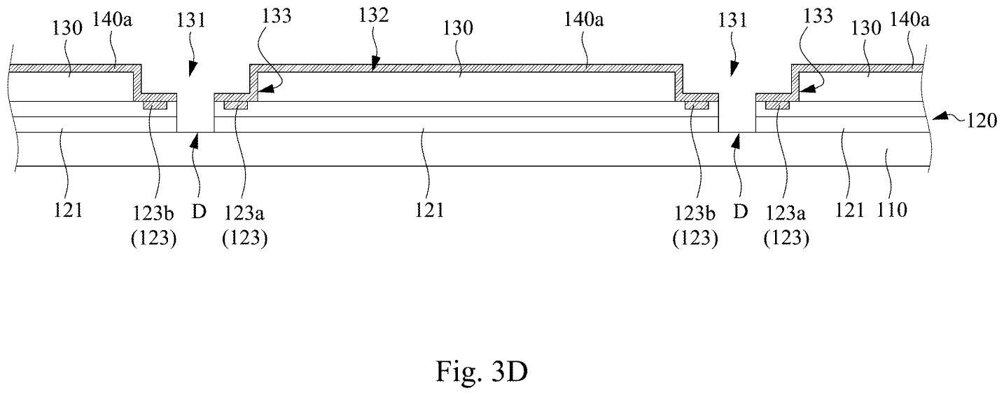

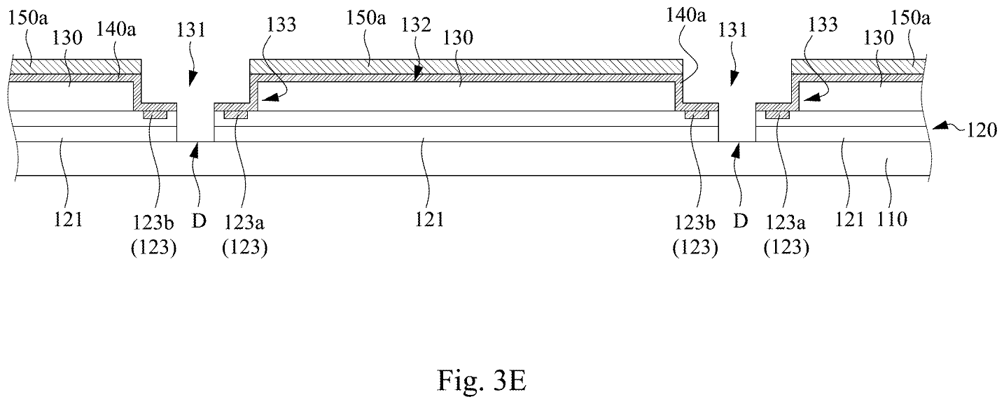

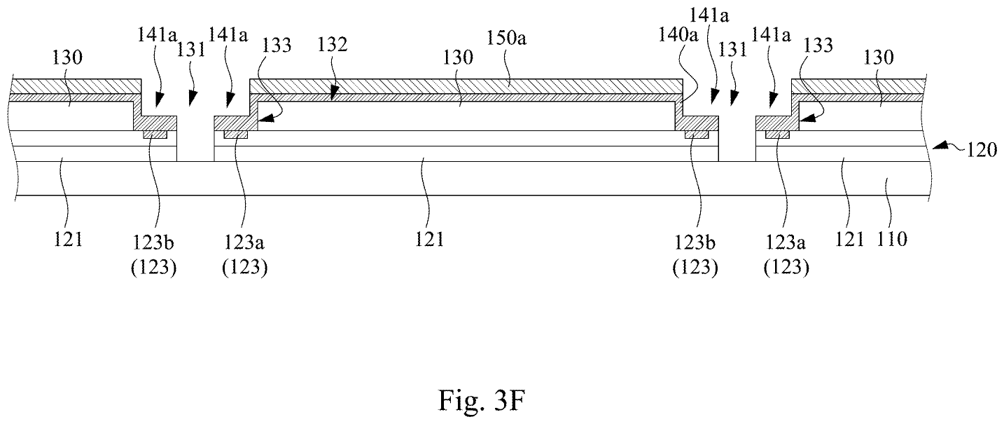

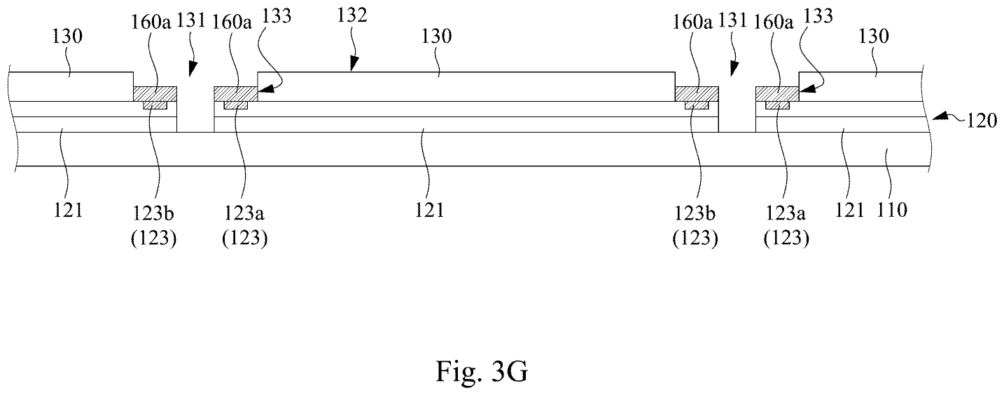

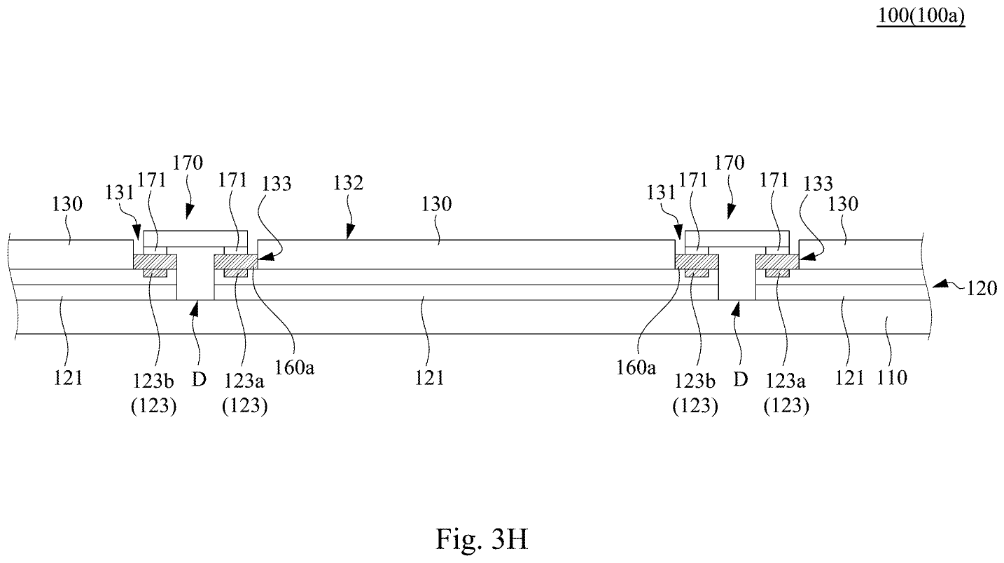

Reference is made to FIG. 2A. FIG. 2A illustrates a flow chart regarding a manufacturing method 200 for the light-emitting device 100. FIG. 3A to FIG. 3H illustrate cross section views of the manufacturing method 200 at different stages. FIG. 3H can represent a cross section view of the light-emitting device 100 taken from the cross section line A-A in FIG. 1A. In some embodiments of the present disclosure, the manufacturing method 200 for fabricating the light-emitting device 100 starts from a step 210, and the step 210 includes providing a substrate. Thereafter, the manufacturing method 200 continues with a step 230 which includes forming a circuit layer on the substrate, and the circuit layer includes a plurality of conductive structures. Each conductive structure has at least a bonding pad, and an interval is located between two adjacent ones of the conductive structures. Next, a step 250 of the manufacturing method 200 is performed, and the step 250 includes forming a plurality of conductive connection portion, in which each conductive connection portion is on each bonding pad. The manufacturing method 200 continues with a step 270 which includes providing a plurality of light-emitting sources, and each light-emitting source crosses each interval and contacts two adjacent ones of the conductive connection portions, such that the semiconductor light-emitting sources are respectively electrically connected to the two adjacent ones of conductive structures.

Reference is made to FIG. 2A and FIG. 3A. FIG. 3A illustrates a cross section view of the substrate 110 in accordance with the step 210. The substrate 110 can be a transparent substrate or non-transparent substrate. For instance, the substrate 110 can be a rigid substrate, a flexible substrate, a glass substrate, sapphire substrate, a silicon substrate, a printed circuit board, a metal substrate, or a ceramic substrate. The present disclosure is not limited in this respect. Moreover, the substrate 110 can has a thickness from about 0.1 mm to about 0.6 mm. The present disclosure is not limited in this respect.

Reference is made to FIG. 2A and FIG. 3B. FIG. 3B illustrates the step 230 which includes forming the circuit layer 120 on the substrate 110. The circuit layer 120 includes the conductive structures 121, and each conductive structure 121 has at least one bonding pad 123. Specifically, the conductive structures 121 are regularly and separately arranged on the substrate 110 along at least one direction, and an interval D is between two adjacent ones of the conductive structures 121. For instance, the interval D is formed between two immediately adjacent ones of the conductive structures, and each the conductive structure 121 has a first bonding pad 123a and a second bonding pad 123b respectively located at two opposite sides of the conductive structure 121. The bonding pad 123 has a thickness smaller than or equal to 1.5 μm. For instance, the bonding pad 123 has a thickness smaller than or equal to 1.4 μm. In some embodiments of the present disclosure, the circuit layer 120 includes titanium copper alloy, molybdenum copper alloy, or platinum. A sputtering process or a vapor deposition process can be performed to the substrate 110, so as to form a conductive layer on the substrate 110. Thereafter, a patterned photoresist layer can be formed on the conductive layer, and then a litho-etch process can be performed to the conductive layer by using the patterned photoresist layer, so as to form the circuit layer 120 which has the patterned conductive structures 121. In some embodiments of the present disclosure, the step of forming the conductive layer, the step of forming the photoresist layer, and the step of performing the litho-etch process can be conducted repeatedly, so as to form the circuit layer 120 and the patterned and multi-layered conductive structures 121. Moreover, a dielectric film can be formed in the multi-layered circuit layer 120, so as to define circuit structures of the circuit layer 120. The dielectric film can be made of silicon dioxide or aluminium nitride, and the present disclosure is not limited in this respect.

Reference is made to FIG. 2A, FIG. 2B, and FIGS. 3C-3G. FIG. 2B further illustrates detail information of step 250 which includes steps 251-257. FIGS. 3C to 3G respectively illustrate cross section views in accordance with the steps 251-257 in FIG. 2. In one or more embodiments of the present disclosure, as shown in FIG. 3C, the step 251 includes providing a reflective layer 130 covering the conductive structures 121, in which the reflective layer 130 includes a plurality of openings 131 respectively aligned with and located above each interval D, and each opening 131 exposes the bonding pads 123 of two adjacent ones of the conductive structures 121. For instance, each opening 131 exposes the bonding pads 123 which belong to two immediately adjacent ones of the conductive structures 121. That is, each opening 131 at least exposes a first bonding pad 123a which belongs to one of the conductive structures 121 and a second bonding pad 123b which belongs to another adjacent one of the conductive structures 121.

In some embodiments of the present disclosure, the reflective layer 130 has reflectance equal to or higher than 85%. Moreover, the reflective layer 130 can have a thickness from about 20 μm to about 30 μm. For instance, the reflective layer 130 has a thickness equal to 25 μm. Moreover, the reflective layer 130 can be made of metal such as, silver, aluminium, chromium, and alloy thereof. The reflective layer can also be a metal mirror, such as silver metal mirror, aluminium mirror, and chromium mirror. The present disclosure is not limited in this respect. In some embodiments of the present disclosure, the reflective layer 130 can be made of a white material which includes titanium dioxide and silicone, and the reflective layer 130 can also be made of another white material which includes titanium dioxide and epoxy. The present disclosure is not limited in this respect. In the step 251, the reflective layer 130 is formed on the circuit layer 120, and an anisotropic process is performed to the reflective layer 130 to form the openings 131 in the reflective layer 130. Therefore, the bonding pads 123 on the conductive structures 121 are exposed by the openings 131. The present disclosure is not limited in this respect.

In one or more embodiments of the present disclosure, as shown in FIG. 3D, the step 253 includes forming the seed layer 140a, in which the seed layer 140a covers a top surface 132 of the reflective layer 130 and extends along sidewalls 133 of the reflective layer 130 to cover the bonding pads 123. That is, the seed layer 140a covers the top surface 132 and the sidewalls 133 of the reflective layer 130, and the seed layer 140a also covers the bonding pads 123. The present disclosure is not limited in this respect. The seed layer 140a can be made of copper, nickel, palladium, silver, gold, tin or alloy thereof, and the seed layer 140a can be formed by a chemical vapor deposition process such as an atomic layer deposition process. The present disclosure is not limited in this respect.

In one or more embodiments of the present disclosure, as shown in FIG. 3E, the step 255 includes forming the photoresist layer 150a to cover the seed layer 140a, and the photoresist layer 150a exposes at least a portion of the seed layer 140a which is on the bonding pads 123. That is, the photoresist layer 150a does not cover nor overlap the bonding pads 123 in a vertical direction. In addition, the photoresist layer 150a covers a portion of the seed layer 140a which is on the reflective layer 130, and the photoresist layer 150a is entirely above the top surface 132 of the reflective layer 130. The present disclosure is not limited in this respect.

In one or more embodiments of the present disclosure, as shown in FIG. 3F and FIG. 3G, the step 257 includes using the seed layer 140a to form a plurality of conductive connection portions 160a, and each conductive connection portion 160a is on each bonding pads 123 of the conductive structures 121. In FIG. 3F, an electroplating process or a chemical plating process is performed to the seed layer 140a, and portions of the seed layer 140a which are not covered by the photoresist layer 150a are thickened to form a plurality of thickening portions 141a of the seed layer 140a. The thickening portions 141a and the seed layer 140a are a single piece of continuous material. In FIG. 3G, the photoresist layer 150a can be removed by any suitable solvent, and the seed layer 140a is partially removed to form the conductive connection portion 160a. For instance, portions of the seed layer 140a which extend from a top surface 132 to sidewalls 133 of the reflective layer 130 are removed. An isotropic etching process with suitable etching solvent can be performed to the seed layer 140a which has the thickening portions, so as to form the conductive connection portions 160a. The present disclosure is not limited in this respect. In other embodiments of the present disclosure, an anisotropic etching process is performed to partially remove the seed layer 140a, so as to form the conductive connection portions 160a. Since the conductive connection portions 160a are formed from the seed layer 140a, such that the conductive connection portions 160a can also be made of copper, nickel, palladium, silver, gold, tin, or alloy thereof. For instance, the conductive connection portions 160a can be made of tin alloy, silver alloy, or copper alloy. The present disclosure is not limited in this respect. Moreover, each conductive connection portion 160a has a thickness from about 8 μm to about 15 μm, and the conductive connection portions 160a are respectively inside the openings 131 and respectively in contact with the sidewalls 133 of the reflective layer 130.

Reference is made to FIG. 3H. FIG. 3H illustrates the step 270 of the manufacturing method 200 which includes providing a plurality of semiconductor light-emitting sources 170, and each semiconductor light-emitting source 170 crosses each interval D and contacts two adjacent ones of the conductive connection portions 160a. Each semiconductor light-emitting sources 170 is above and aligned with each interval D. Therefore, the semiconductor light-emitting sources 170 are respectively electrically connected to the bonding pads 123 which respectively belong to the two adjacent ones of the conductive structures 121, such that the light-emitting device 100a is obtained.

Moreover, the semiconductor light-emitting sources 170 can include light-emitting diode chips which have nitride compound semiconductor stacking layers and two electrodes 171. The nitride compound semiconductor stacking layers can include an n-type semiconductor layer, an active layer, and a p-type semiconductor layer, wherein the nitride compound semiconductor stacking layers can include III-V semiconductor material or II-VI semiconductor material, such as selected from a nitride compound semiconductor group which is at least consisted of GaN, InGaN, AlN, InN, AlGaN, and InGaAlN. The two electrodes 171 which can include a positive electrode and a negative electrode are on the same side of the nitride compound semiconductor stacking layers. The negative electrode is in contact with the n-type semiconductor layer, and the positive is in contact with the p-type semiconductor layer. As shown in FIG. 3G, the two electrodes 171 of each semiconductor chips are connected to two adjacent ones of the conductive connection portions 160a in a flip-chip manner. Specifically, two electrodes 171 of each semiconductor light-emitting source 170 cross a first bonding pad 123a and a second bonding pad 123b which respectively belonging to two adjacent ones of the conductive connection portions 160a. The electrodes 171 can be made of metal, such as gold, silver, and tin. The electrodes 171 can be fixed to the conductive connection portions 160a by a soldering process or an eutectic process, so as to stably fix the semiconductor light-emitting sources 170 to the conductive connection portions 160a. Since the conductive connection portions 160a can be stably connected between the semiconductor light-emitting sources 170 and the bonding pads 123, the conductive connection portions 160a can improve the conductive property and the mechanical property between the circuit layer 120 and the semiconductor light-emitting sources 170.

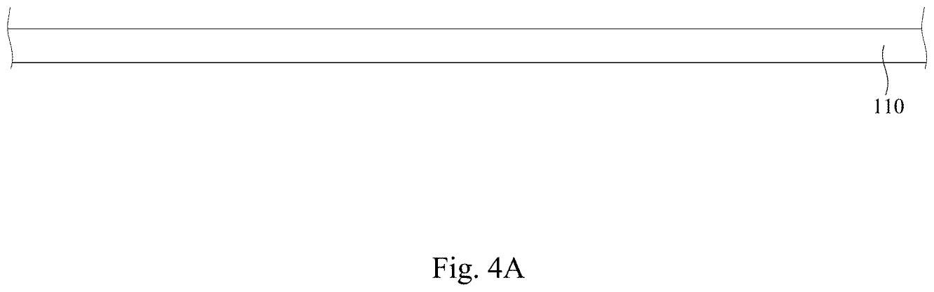

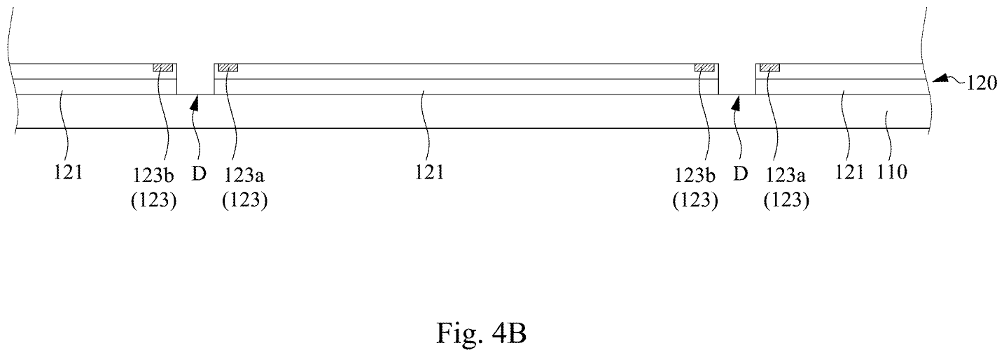

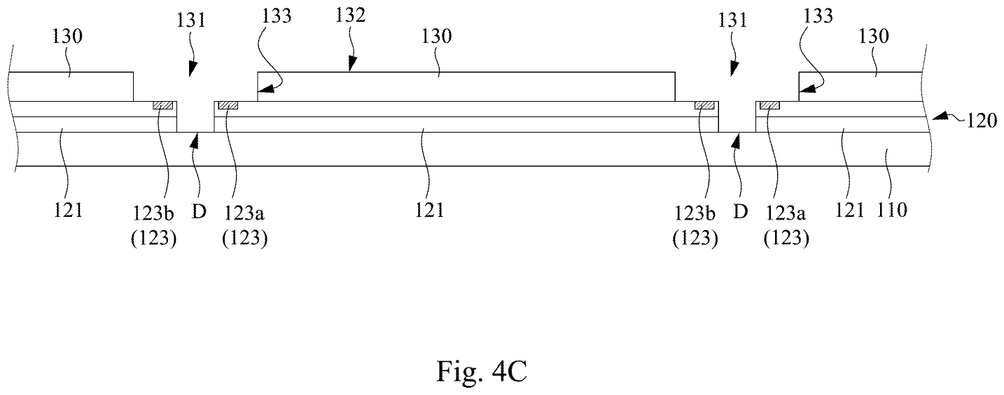

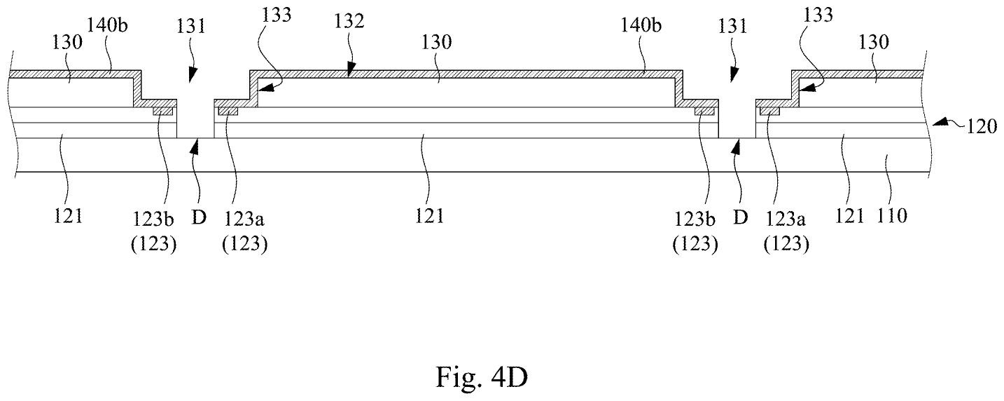

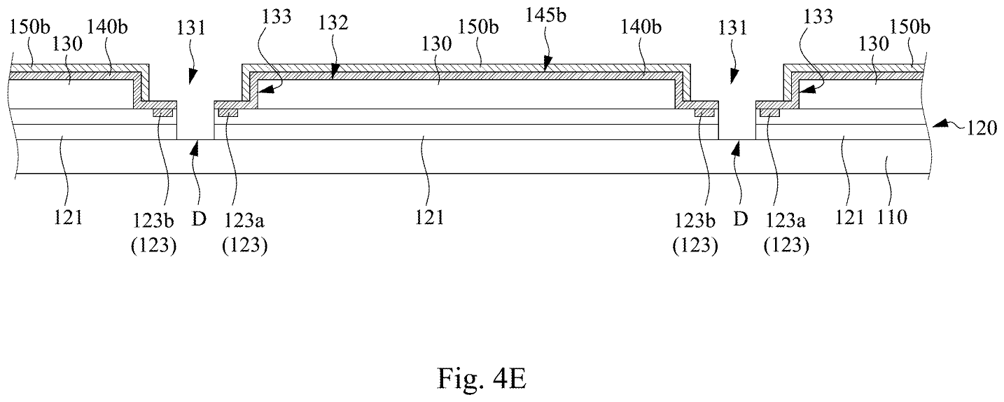

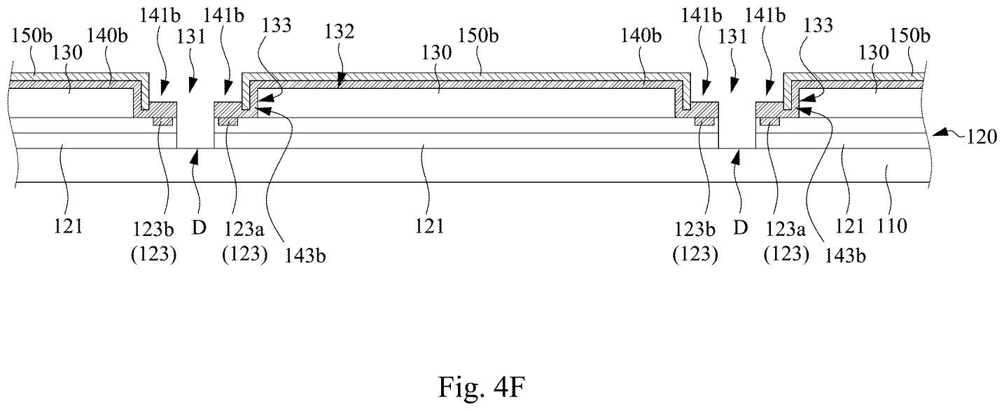

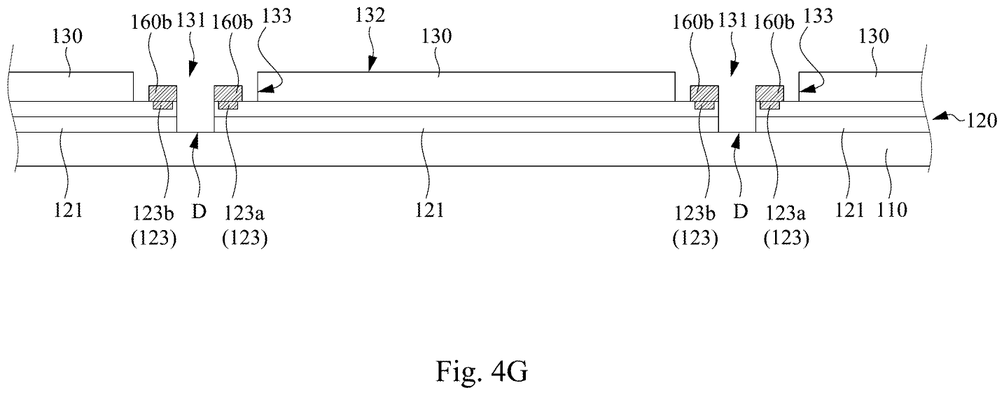

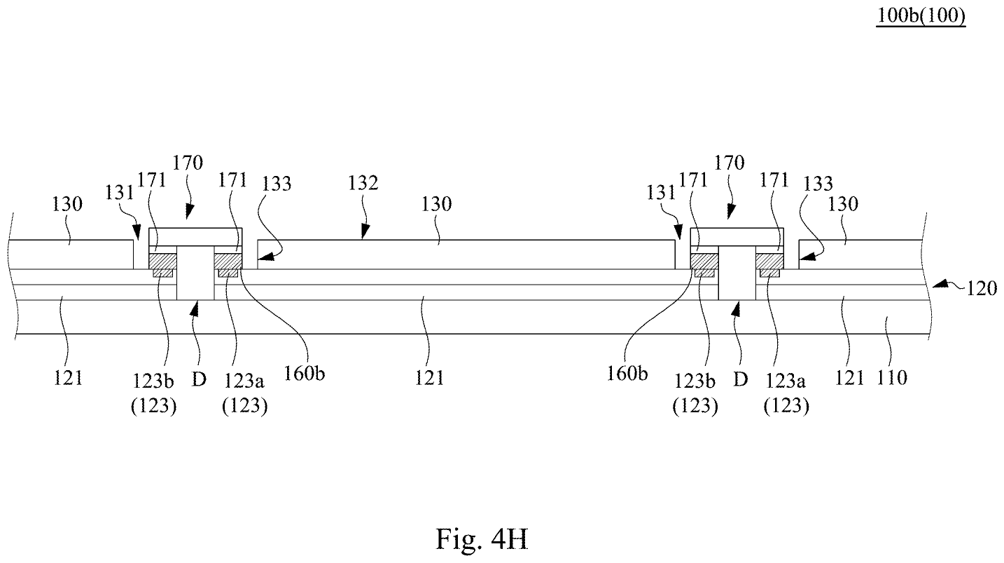

In some embodiments of the present disclosure, FIGS. 4A-4H respectively illustrate cross section views of the manufacturing method 200 in FIG. 2A at different stages, and FIG. 4H can represent a cross section view of the light-emitting device 100 in FIG. 1A. FIGS. 4A-4D are substantially the same as FIGS. 3A-3D, and the same information thereof is not repeated. Reference is made to FIG. 4E. FIG. 4E can represent the step 255 of FIG. 2B which includes forming a photoresist layer 150b on a top surface 145b of the seed layer 140b, and the photoresist layer 150b exposes portions of the seed layer 140b on the bonding pads 123. That is, the photoresist layer 150b does not overlap the bonding pads 123 nor the portions of the seed layer 140b in the vertical direction. In addition, the photoresist layer 150b covers other portions of the seed layer 140b on the reflective layer 130, and the photoresist layer 150b extends from a top surface 132 of the reflective layer 130 to sidewalls 133 of the reflective layer 130. In other words, the photoresist layer 150b extends from a top surface 132 of the reflective layer 130 to sidewalls 133 of the reflective layer 130, and therefore a portion of the photoresist layer 150b is horizontal to sidewalls 133 of the reflective layer 130. Therefore, the photoresist layer 150b covers portions of the seeds layer 140b which is on a top surface 132 of the reflective layer 130 and extends to sidewalls 133 of the reflective layer 130. The present disclosure is not limited in this respect. Specifically, the seed layer 140b is made of copper, nickel, palladium, silver, gold, tin, or alloy thereof, and a chemical vapor deposition process such as atomic layer deposition process is performed to the seed layer 140b. The present disclosure is not limited in this respect.

In one or more embodiments of the present disclosure, FIGS. 4F-4G can represent the step 257 which includes using the seed layer 140b to form conductive connection portions 160b, and each conductive connection portion 160b is located on each bonding pad 123 of the conductive structures 121. In FIG. 4F, a sputtering process, an electroplating process, or a chemical plating process is performed to the seed layer 140b, and the portions of the seed layer 140b which are not covered by the photoresist layer 150a are thickened. Therefore, the thickening portions 141b of the seed layer 140b are formed, and the seed layer 140b and the thickening portions 141b are a single piece of continuous material. The photoresist layer 150b covers a portion of the seed layer 140b which extends from a top surface 132 of the reflective layer 130 to sidewalls 133 of the reflective layer 130. Therefore, concave portions 143b are respectively formed between the thickening portions 141b and the reflective layer 130. The present disclosure is not limited in this respect.

In FIG. 4G, the photoresist layer 150b can be removed by suitable solvent, and the seed layer 140b is partially removed to form the conductive connection portions 160b. For instance, a portion of the seed layer 140b which extends from the top surface 132 to the sidewalls 133 of the reflective layer 130 is partially removed. In some embodiments of the present disclosure, an isotropic etching process with a suitable solvent can partially remove the seed layer 140b, so as to obtain the conductive connection portions 160b. The present disclosure is not limited in this respect. In other embodiments of the present disclosure, an anisotropic etching process partially removes the seed layer 140b, so as to form the conductive connection portions 160b. In FIG. 4G, the conductive connection portions 160b are spaced apart from the reflective layer 130, and the conductive connection portions 160b are inside the openings 131 and spaced apart from the sidewalls 133 the reflective layer 130. Since the conductive connection portions 160b are formed from the seed layer 140b, the conductive connection portions 160b can also include copper, nickel, palladium, silver, gold, tin, or alloy thereof. For instance, the conductive connection portions 160b can be made of tin alloy, silver alloy, or copper alloy. The present disclosure is not limited in this respect.

Reference is made to FIG. 4H. FIG. 4H can represent the step 270 of the manufacturing method 200 according to FIG. 2A, and the step 270 includes providing a plurality of the semiconductor light-emitting sources 170. Each semiconductor light-emitting source 170 crosses each interval D and contacts two adjacent ones of the conductive connection portions 160b, and thus each semiconductor light-emitting source 170 is electrically connected to two adjacent ones of the conductive structures 121, so as to obtain the light-emitting device 100b. Specifically, each semiconductor light-emitting source 170 is in contact with a first bonding pad 123a and a second bonding pad 123b respectively belonging to two adjacent ones of the conductive connection portions 160b. Moreover, each semiconductor light-emitting sources 170 has two electrodes 171 which join two adjacent ones of the conductive connection portions 160b in a flip-chip manner. A soldering process can be performed to the bonding pads 123, the conductive connection portions 160b, and the semiconductor light-emitting sources 170, so as to stably fix the semiconductor light-emitting sources 170 to the conductive connection portions 160b. Since the conductive connection portions 160b can be stably connected between semiconductor light-emitting sources 170 and the bonding pads 123, respectively, the conductive connection portions 160b can improve the conductive property and the mechanical property between the circuit layer 120 and the semiconductor light-emitting sources 170. Specifically, each conductive connection portion 160b has a width substantially equal to a width of each electrode 171, and the semiconductor light-emitting sources 170 in small size can be correctly arranged at a specific position of the circuit layer 120 after the conductive connection portions 160b and the electrodes 171 are soldered by a soldering furnace.

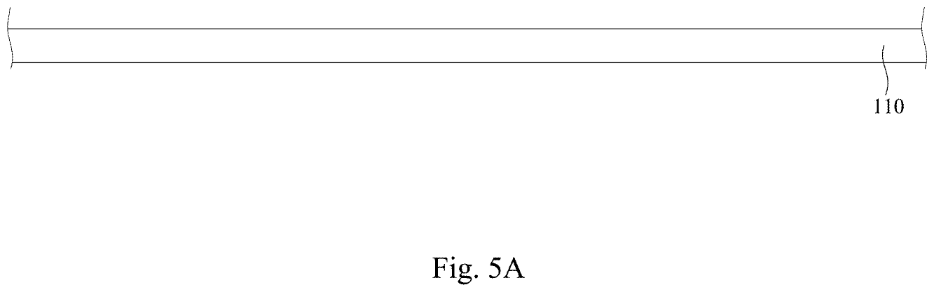

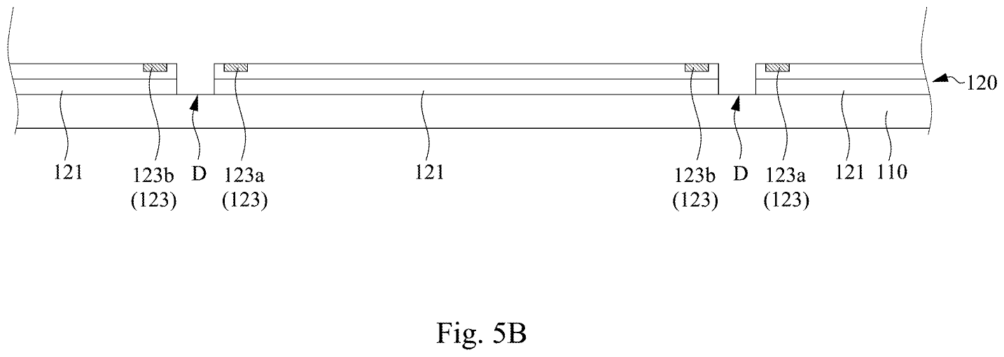

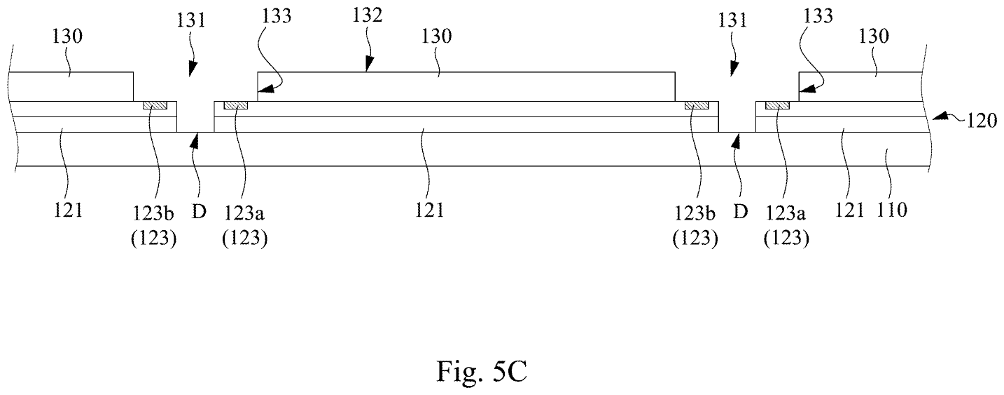

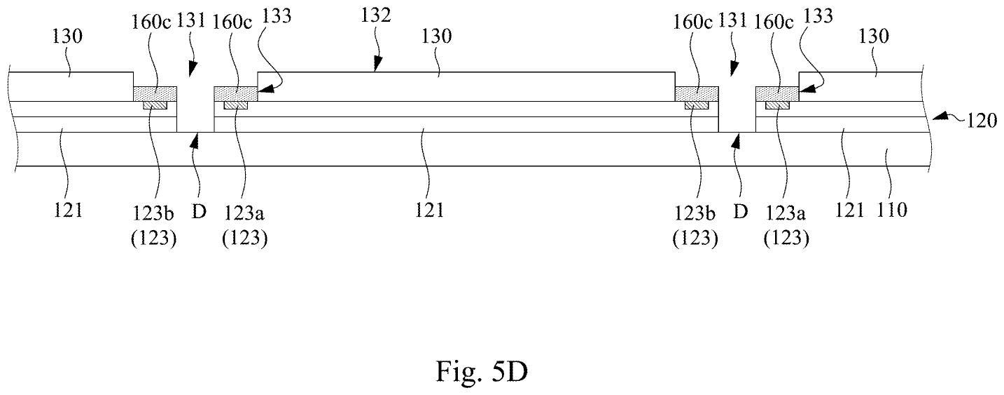

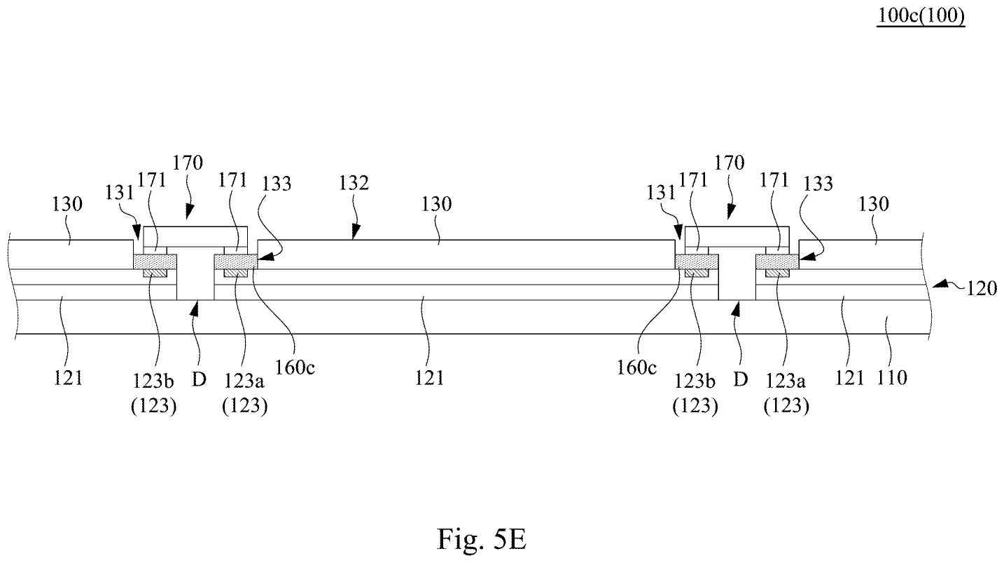

In some embodiments of the present disclosure, FIGS. 5A-5E illustrate cross section views of the manufacturing method 200 at different stages. FIG. 5E can represent a cross section view of the light-emitting device 100 taken from the cross section line A-A. FIGS. 5A-5B are substantially the same as FIGS. 3A -3B, and the same information thereof is not repeated. Reference is made to FIGS. 5C-5D. FIGS. 5C-5D can represent the step 250 according to the manufacturing method 200. The step 250 includes forming a plurality of conductive connection portions 160c, and each conductive connection portion 160c is on each bonding pad 123. In FIG. 5C, the reflective layer 130 covers the conductive structures 121, and the reflective layer 130 includes a plurality of openings 131 respectively aligned with each interval D. Each opening 131 exposes the bonding pads 123 which belong to two adjacent ones of the conductive structures 121. Reference is made to FIG. 5D, a printing process or a spraying process is performed in each opening 131, so as to form conductive slurry on each bonding pad 123. The conductive slurry can include copper slurry, silver slurry, gold slurry, or solder paste. Thereafter, a thermal drying process is performed to the conductive slurry, so as to form the conductive connection portions 160c. The conductive connection portions 160c contact the sidewalls 133 of the reflective layer 130. More specifically, the conductive connection portions 160c contact the sidewalls 133 in the openings 131. In some embodiments of the present disclosure, the printing process to form the conductive slurry is a paste printing process which can accurately adjust the size and the shape of the conductive connection portions 160c, so as to efficiently join the bonding pads 123 and the electrodes 171, respectively.

Reference is made to FIG. 5E. FIG. 5E can represent the step 270 in FIG. 2A, and the step 270 includes providing a plurality of the semiconductor light-emitting sources 170. Each semiconductor light-emitting sources 170 crosses each interval D and contacts two adjacent ones of the conductive connection portions 160c, and each semiconductor light-emitting source 170 is electrically connected to the bonding pads 123 which belong to two adjacent ones of the conductive structures 121, so as to obtain the light-emitting device 100c. Specifically, each semiconductor light-emitting source 170 crosses a first bonding pad 123a and a second bonding pad 123b respectively belonging two adjacent ones of the conductive connection portions 160c. Moreover, each semiconductor light-emitting source 170 has two electrodes 171 connected to two adjacent ones of the conductive connection portions 160c in a flip-chip manner, a soldering process can be performed to the bonding pads 123, the conductive connection portions 160c, and the semiconductor light-emitting sources 170. Therefore, the semiconductor light-emitting sources 170 can be fixed to and located on the conductive connection portions 160c. Since the conductive connection portions 160c can be stably connected between the semiconductor light-emitting sources 170 and the bonding pads, the conductive connection portions 160c can improve the conductive property and mechanical property between the circuit layer 120 and the semiconductor light-emitting sources 170.

The following paragraphs describe different embodiments regarding the light-emitting device 100 in FIG. 1A, and some details disclosed in the previous paragraphs are not repeated. Reference is made to FIG. 3H, and the light-emitting device 100a includes the substrate 110, the circuit layer 120, the conductive connection portions 160a, and the semiconductor light-emitting sources 170. The circuit layer 120 is located on the substrate 110, and the circuit layer 120 includes the conductive structures 121. Each conductive structure 121 has at least one bonding pad 123, and each interval D is respectively located between two adjacent ones of the conductive structures 121. Moreover, each conductive connection portions 160a is located on each bonding pad 123, and each semiconductor light-emitting source 170 crosses each interval D and contacts two adjacent ones of the conductive connection portions 160a, such that each semiconductor light-emitting source 170 is electrically connected to the bonding pads 123 of two adjacent ones of the conductive structures 121. The conductive structures 121 are regularly arranged along a direction, and each interval D is between two adjacent ones of the conductive structures 121. Accordingly, each conductive structure 121 has a first bonding pad 123a and a second bonding pad 123b respectively located at two opposite sides of each conductive structure 121.

In some embodiments of the present disclosure, the light-emitting device 100a further includes the reflective layer 130, and the reflective layer 130 is located on the circuit layer 120 to cover the conductive structures 121. The reflective layer 130 includes the openings 131 which correspond to and communicate with each interval D, respectively. Each opening 131 exposes the bonding pads 123 which belong to two adjacent ones of the conductive structures 121, and thus each opening 131 exposes the first bonding pad 123a and the second bonding pad 123b which respectively belong to the two adjacent ones of the conductive structures 121. Specifically, each semiconductor light-emitting source 170 crosses and contacts the conductive connection portion 160 on the first bonding pad 123a of one of the conductive structures 121 and the conductive connection portion 160 on the second bonding pad 123b of an adjacent one of the conductive structures 121. Moreover, the conductive connection portions 160a are in contact with the sidewalls 133 of reflective layer 130. More specifically, the conductive connection portions 160a are in contact with the sidewalls 133 in the openings 131, so as to fix the semiconductor light-emitting sources 170. The reflective layer 130 can be a metal reflective layer which has a metal mirror reflection layer or a white reflection layer. The method for forming the reflective layer 130 has been described in the previous paragraphs, and thus the related details are not repeated.

In one or more embodiments of the present disclosure, two electrodes 171 of each semiconductor light-emitting sources 170 are located on two adjacent ones of the conductive connection portions 160a, and the two electrodes 171 are electrically connected to the two adjacent ones of the conductive connection portions 160a in a flip-chip manner. Therefore, the two electrodes 171 are electrically connected to the bonding pads 123 which belong to the two adjacent ones of the conductive structures 121. In addition, each electrode 171 is not higher than the top surface 132 of the reflective layer 130. That is, bonding surfaces which are respectively between the electrodes 171 and the conductive connection portions 160a are lower than the top surface 132 of the reflective layer 130, and the reflective layer 130 can efficiently adjust light generated by the semiconductor light-emitting sources 170 and improve luminance of the light-emitting device 100a. The present disclosure is not limited in this respect.

Reference is made to FIG. 4H. In some embodiments of the present disclosure, the light-emitting device 100b includes the substrate 110, the circuit layer 120, the conductive connection portions 160b, and the semiconductor light-emitting sources 170. The light-emitting device 100b is substantially the same as the light-emitting device 100a, but the conductive connection portions 160b are spaced apart from sidewalls 133 of the reflective layer 130. That is, the conductive connection portions 160b are spaced apart from the sidewalls 133 in the openings 131. Each conductive connection portion 160b has a width equal to a width of each electrode 171, and the semiconductor light-emitting sources 170 in small size can be correctly arranged at a specific position of the circuit layer 120 after the conductive connection portions 160b and the electrodes 171 are soldered by a soldering furnace. The method for manufacturing the conductive connection portions 160b and the details thereof have been described in the previous paragraphs, and thus the disclosed information is not repeated.

Reference is made to FIG. 5E. The light-emitting device 100c includes the substrate 110, the circuit layer 120, the conductive connection portions 160c, and the semiconductor light-emitting sources 170. The light-emitting device 100b is substantially the same as the light-emitting device 100c, but the conductive connection portions 160c are different from the conductive connection portions 160b. The conductive connection portions 160c are made of conductive slurry, such as copper slurry, silver slurry, gold slurry, and solder paste. A printing process or a spraying process is performed to each bonding pad 123, so as to form conductive slurry on each bonding pad 123. Thereafter, a thermal drying process is performed to the conductive slurry, so as to form the conductive connection portions 160c. In some embodiments of the present disclosure, the printing process used to form the conductive slurry is a paste printing process which can accurately adjust the size and the shape of the conductive connection portions 160c, so as to efficiently join the bonding pads 123 and the electrodes 171. Moreover, the conductive connection portions 160c are in contact with the sidewalls 133 of reflective layer 130. More specifically, the conductive connection portions 160c are in contact with the sidewalls 133 in the openings 131. The present disclosure is not limited in this respect. In some other embodiments of the present disclosure, the conductive connection portions 160c are spaced apart from the reflective layer 130, and thus the conductive connection portions 160c are spaced apart from the sidewalls 133 in the openings 131, so as to fix the semiconductor light-emitting sources 170.

In embodiments of the present disclosure, a light-emitting device which has conductive connection portions and a method for fabricating the same are provided, and the conductive connection portions can be stably connected between semiconductor light-emitting source and bonding pads, so as to improve the conductive property and the mechanical property thereof. Moreover, the light-emitting devices can be applied in various light-emitting apparatuses, display apparatuses, and back light modules of liquid crystal display apparatuses.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light-emitting device, comprising:
a substrate;
a circuit layer on the substrate having a plurality of conductive structures, wherein each conductive structure comprises at least one bonding pad, and an interval is between two adjacent ones of the plurality of conductive structures;
a plurality of conductive connection portions, wherein each conductive connection portion is correspondingly disposed on each bonding pad; and
a plurality of semiconductor light-emitting sources, wherein each semiconductor light-emitting source crosses each interval and contacts two adjacent ones of the plurality of conductive connection portions, such that the semiconductor light-emitting sources are respectively electrically connected to two adjacent ones of the plurality of conductive structures.

2. The light-emitting device of claim 1, further comprising a reflective layer disposed on the circuit layer and covering the conductive structures, wherein the reflective layer has a plurality of openings, each opening is aligned with each interval, and the at least one bonding pad is disposed in each opening.

3. The light-emitting device of claim 2, wherein the conductive connection portions respectively contact side surfaces of the reflective layer.

4. The light-emitting device of claim 2, wherein the conductive connection portions are separated from side surfaces of the reflective layer.

5. The light-emitting device of claim 1, wherein the conductive connection portions comprise copper, nickel, palladium, silver, gold, tin, or alloy thereof.

6. The light-emitting device of claim 1, wherein the conductive connection portions are made from copper slurry, silver slurry, gold slurry, or solder paste.

7. The light-emitting device of claim 2, wherein each semiconductor light-emitting source comprises a light-emitting diode chip having two electrodes respectively on the two adjacent conductive connection portions.

8. The light-emitting device of claim 7, wherein each electrode is not higher than a top surface of the reflective layer.

9. The light-emitting device of claim 2, wherein the reflective layer comprises a white reflective layer or a metal reflective layer.

10. A method for manufacturing a light-emitting device comprising:
providing a substrate;
forming a circuit layer which has a plurality of conductive structures on the substrate, wherein each conductive structure has a least one bonding pad, and an interval is formed between two adjacent ones of the plurality of the conductive structures;
forming a plurality of conductive connection portions, wherein each conductive connection portion is correspondingly disposed on each bonding pad; and
providing a plurality of semiconductor light-emitting sources, wherein each semiconductor light-emitting source crosses each interval and contacts two adjacent ones of the plurality of conductive connection portions, such that the semiconductor light-emitting sources are respectively electrically connected to two adjacent ones of the plurality of conductive structures.

11. The method of claim 10, wherein forming the plurality of conductive connection portions further comprises:
providing a reflective layer covering the conductive structures, wherein the reflective layer has a plurality of openings respectively aligned with each interval, each interval exposes the bonding pad of each two adjacent conductive structures;
forming a seed layer which covers a top surface of the reflective layer and extends along sidewalls of the openings to cover the exposed bonding pads;
forming a photoresist layer on the seed layer, wherein the photoresist layer exposes the partial seed layer on the bonding pads; and
using the seed layer to form the conductive connection portions.

12. The method of claim 11, wherein a portion of the seed layer on a top surface of the reflective layer is covered by the photoresist layer.

13. The method of claim 11, wherein a portion of the seed layer which extends from a top surface of the reflective layer to side surfaces of the openings is covered by the photoresist layer.

14. The method of claim 11, wherein forming the conductive connection portions comprises:
forming a plurality of thickening portions from the seed layer;
removing the photoresist layer; and
partially removing the seed layer.

15. The method of claim 11, wherein forming the conductive connection portions comprises:
forming a plurality of thickening portions on the seed layer;
removing the photoresist layer; and
removing a portion of the seed layer which is on a top surface of the reflective layer.

16. The method of claim 11, wherein the seed layer comprises copper, nickel, palladium, silver, gold, tin, or alloy thereof.

17. The method of claim 10, wherein forming the conductive connection portions comprises:
performing a printing process or a spraying process to form conductive slurry on each bonding pad.

18. The method of claim 17, wherein the printing process comprises a paste printing process.

19. The method of claim 10, wherein forming the conductive connection portions comprises:
providing a reflective layer covering the conductive structures, wherein the reflective layer has a plurality of openings respectively aligned with the intervals, the at least one bonding pad is disposed in each opening; and
performing a printing process or a spraying process in each opening to form conductive slurry on each bonding pad, so as to form the conductive connection portions, wherein the conductive connection portions respectively contact side surfaces of the reflective layer.

20. The method of claim 10, wherein each semiconductor light-emitting source comprises a light emitting diode chip having two electrodes respectively electrically connected to the two adjacent conductive connection portions by a flip-chip manner.
